(19) United States
(12) Patent Application Publication
(10) Pub. No.: US 2013/0058503 A1
(43) Pub. Date: Mar. 7, 2013

(54) AUDIO PROCESSING APPARATUS, AUDIO PROCESSING METHOD, AND AUDIO OUTPUT APPARATUS

(71) Applicants: Takashi Kato, Tokyo (JP); Noboru Murabayashi, Saitama (JP)

(72) Inventors: Takashi Kato, Tokyo (JP); Noboru Murabayashi, Saitama (JP)

(73) Assignee: Sony Corporation, Tokyo (JP)

(21) Appl. No.: 13/568,480

(22) Filed: Aug. 7, 2012

(30) Foreign Application Priority Data
Sep. 7, 2011 (JP) 2011-194557

(51) Int. Cl. H03G 3/20

(52) U.S. Cl. 381/107

(57) ABSTRACT

An audio processing apparatus includes a user detection unit that detects the presence or absence of a user; a user information obtaining unit that obtains user information about a user that is detected by the user detection unit; and an audio processing unit that performs a process for accentuating predetermined audio contained in input audio on the basis of the user information.

### BACKGROUND

The present technology relates to an audio processing apparatus, an audio processing method, and an audio output apparatus. More particularly, the present technology relates to an audio processing apparatus that performs a process for automatically correcting audio on the basis of the hearing ability of a user who is listening to the audio, to an audio processing method therefor, and to an audio output apparatus therefor.

In the case where hearing ability has deteriorated due to aging, it becomes difficult to hear audio when viewing a movie, a television program or the like and in a phone call conversation, it is difficult to sufficiently enjoy the content, the conversation, and the like, and stress is felt by the user.

Therefore, there has been proposed a phone set in which a hearing-impaired person can adjust a voice output level in accordance with his/her own auditory sense for each frequency component band (Japanese Unexamined Patent Application Publication No. 7-23098).

### SUMMARY

The technology disclosed in Japanese Unexamined Patent Application Publication No. 7-23098 aims to allow adjustment of a voice output level by a user on his/her own. Therefore, in the case where a user has not noticed a deterioration in their hearing ability due to aging, the functions thereof are not used. Furthermore, even if a user has noticed a deterioration in their hearing ability, there may be a case where the user feels a psychological resistance to using the adjustment function, and does not use the adjustment function.

Accordingly, it is desirable to provide an audio processing apparatus that performs a process for automatically correcting audio on the basis of the hearing ability of a user, an audio processing method therefor, and an audio output apparatus therefor.

According to a first embodiment of the technology, there is provided an audio processing apparatus including: a user detection unit that detects the presence or absence of a user; a user information obtaining unit that obtains user information about a user that is detected by the user detection unit; and an audio processing unit that performs a process for accentuating predetermined audio contained in input audio on the basis of the user information.

According to a second embodiment of the technology, there is provided an audio processing method including: detecting the presence or absence of a user; obtaining user information about the detected user; and accentuating predetermined audio contained in input audio on the basis of the user information.

According to a third technology, there is provided an audio output apparatus including: an audio processing apparatus including a user detection unit that detects the presence or absence of a user, a user information obtaining unit that obtains user information about a user that is detected by the user detection unit, and an audio processing unit that performs a process for accentuating predetermined audio contained in input sound on the basis of the user information; and a directional speaker that outputs audio on which processing has been performed by the audio processing apparatus.

According to the present technology, since a process for automatically correcting audio is performed on the basis of the hearing ability a user who is listening to the audio, it is possible to provide a hearing environment suitable for each user.

### BRIEF DESCRIPTION OF THE DRAWINGS

FIG. 1 is a block diagram illustrating the configuration of an audio processing apparatus according to the present technology;

FIG. 2 is a block diagram illustrating the configuration of an audio processing unit;

FIG. 3 illustrates characteristics of persons in age brackets;

FIG. 4 illustrates the amount of correction for frequency characteristics of audio in a first embodiment of the present technology;

FIG. 5 is a block diagram illustrating the configuration of an audio output apparatus including the audio processing apparatus according to the first embodiment of the present technology;

FIG. 6 is a flowchart illustrating the flow of audio processing performed in the audio output apparatus including the audio processing apparatus;

FIG. 7 illustrates characteristics of hearing abilities of persons in age brackets;

FIG. 8 illustrates the amount of correction for frequency characteristics of audio in a second embodiment of the present technology;

FIG. 9 is a block diagram illustrating the configuration of an audio output apparatus including an audio processing apparatus according to a third embodiment of the present technology.

FIG. 10 illustrates an outline of an audio output apparatus;

FIG. 11 is a block diagram illustrating the configuration of an audio output apparatus including an audio processing apparatus according to a fourth embodiment of the present technology;

FIG. 12 illustrates an example of the configuration of a speaker and a driving unit;

FIG. 13 is a flowchart illustrating the flow of audio processing performed in an audio output apparatus including an audio processing apparatus;

FIG. 14 is a block diagram illustrating the configuration of an audio output apparatus including an audio processing apparatus according to a fifth embodiment of the present technology;

FIG. 15 illustrates an outline of an audio output apparatus; and

FIG. 16 is a flowchart illustrating the flow of audio processing performed in the audio output apparatus including an audio processing apparatus.

### DETAILED DESCRIPTION OF EMBODIMENTS

Embodiments of the present technology will be described below with reference to the drawings. However, the present technology is not limited to only the embodiments described below. The description will be given in the following order.

### 1. First Embodiment

### 1-1. Configuration of Audio Processing Apparatus

### 1-2. Configuration of Audio Output Apparatus Including Audio Processing Apparatus

### 1-3. Audio Processing

### 2. Second Embodiment

### 2-1. Audio Processing

### 3. Third Embodiment

### 3-1. Configuration of Audio Output Apparatus Including Audio Processing Apparatus

### 4. Fourth Embodiment

### 4-1. Configuration of Audio Output Apparatus Including Audio Processing Apparatus

### 4-2. Process in the Fourth Embodiment

### 5. Fifth Embodiment

### 5-1. Configuration of Audio Output Apparatus Including Audio Processing Apparatus

### 5-2. Process in Fifth Embodiment

### 6. Modification

### 1. Embodiment

### 1-1. Configuration of Audio Processing Apparatus

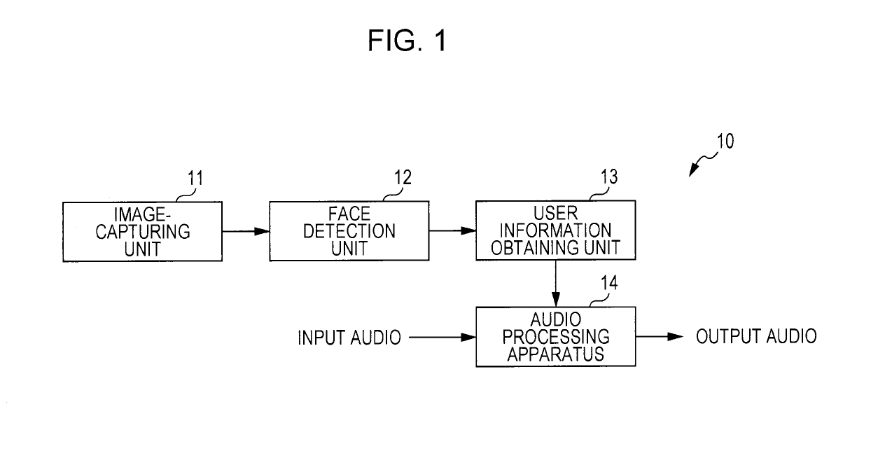

First, a description will be given, with reference to FIG. 1, of the configuration of an audio processing apparatus 10. FIG. 1 is a block diagram illustrating the configuration of the audio processing apparatus 10 according to the present technology. The audio processing apparatus 10 is constituted by an image-capturing unit 11, a face detection unit 12, a user information obtaining unit 13, and an audio processing unit 14.

The image-capturing unit 11 captures an image of a user so as to obtain image data. The image-capturing unit 11 is formed of an image-capturing element, such as a charge coupled device (CCD) or a complementary metal oxide semiconductor (CMOS), an image processing circuit that photoelectrically converts a light image obtained by the image-capturing element into an amount of charge and outputs it as image data, and the like. The image data obtained by the image-capturing unit 11 is supplied to the face detection unit 12.

The face detection unit 12 detects a face of a person from within the image associated with the image data supplied from the image-capturing unit 11. Regarding the face detection method, methods based on template matching based on the shape of a face, template matching based on the luminance distribution of a face, the feature quantity of a portion of a flesh color and a face of a human being, which is contained in the image, and the like, can be used. Furthermore, these techniques may be combined to increase the accuracy of face detection. The face image data representing the face of the user, which is detected by the face detection unit 12, is supplied to the user information obtaining unit 13. As described above, in the present embodiment, by detecting a face from within the image obtained by the image-capturing unit 11, a user is detected. The image-capturing unit 11 and the face detection unit 12 correspond to a user detection unit in claims.

The user information obtaining unit 13 obtains the user information of the user, which is a subject, on the basis of the face image data supplied from the face detection unit 12. In the present embodiment, the user information is an age bracket in which the age of the user is contained. The age of the user can be estimated from, for example, the features of the face of the user. Specifically, the contour of the face of the user, and the features of each of the units forming the eyes, the nose, the cheeks, the ears, and the like are extracted, a matching process is performed between those extracted features and the prestored features of a standard face on an age basis, and the age of the user is estimated from the standard face of the age group, having the highest correlation. However, any technology may be used as long as the technology can estimate the age of the user. For example, the technology disclosed in Japanese Unexamined Patent Application Publication No. 2008-282089 may be used.

In the present embodiment, it is sufficient that the age bracket of the user, for example, less than 20 years old, 20 to 30 years old, 30 to 40 years old, 40 to 50 years old, 50 to 60 years old, or 60 years old or older, is obtained. However, this description does not negate the estimation of a specific age, and audio processing described below may be performed on the basis of a specific age. The user information indicating the age bracket of the user is supplied to the audio processing unit 14.

In the case where faces of a plurality of persons are detected from the image obtained by the image-capturing unit 11, the highest age bracket from within the age brackets of the plurality of users may be supplied as user information to the audio processing unit 14. The present technology provides a hearing environment satisfactory for a user who has become difficult to hear audio due to aging. Therefore, it is considered that setting the highest age bracket as user information is in line with the object of the present technology. Furthermore, the average of the age brackets of the plurality of users may be calculated, and the average age bracket may be set as user information.

Input audio, and user information from the user information obtaining unit 13 are supplied to the audio processing unit 14. The audio processing unit 14 performs predetermined audio processing on input audio on the basis of the user information. Examples of input audio include audio from a television receiver, audio of content, which is output from various reproduction devices, such as a digital versatile disc (DVD) player, or a Blu-ray disc player.

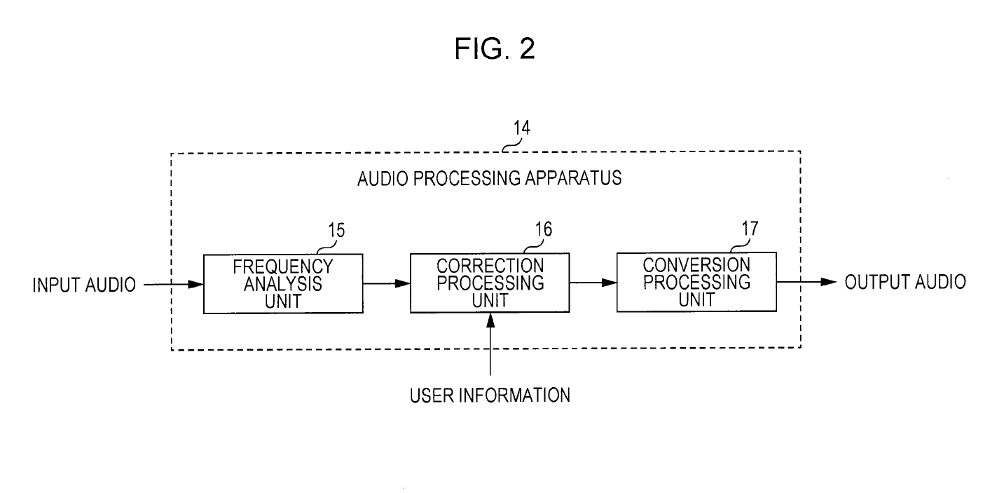

FIG. 2 is a block diagram illustrating a detailed configuration of the audio processing unit 14. The audio processing unit 14 is constituted by a frequency analysis unit 15, a correction processing unit 16, and a conversion processing unit 17.

An audio signal is input to the frequency analysis unit 15. The frequency analysis unit 15 performs frequency analysis on the input audio signal so as to convert the audio signal from a signal in a time domain to a signal in a frequency domain. For the technique of frequency analysis, for example, a high-speed Fourier transform (FFT: Fast Fourier Transform) can be used. Then, the frequency domain signal is supplied to the correction processing unit 16.

The correction processing unit 16 performs audio processing on the supplied audio signal on the basis of the user information. The audio signal on which audio processing has been performed is supplied to the conversion processing unit 17. Audio processing is performed in the following manner.

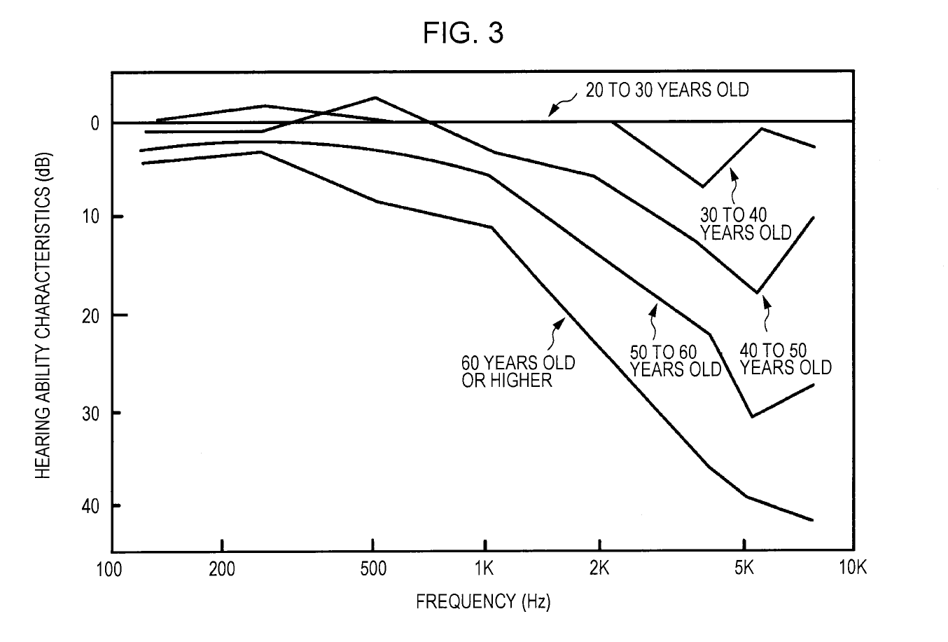

FIG. 3 illustrates hearing ability characteristics of persons in age brackets by plotting frequency in the horizontal axis and the hearing ability characteristics in the vertical axis. As shown in FIG. 3, the hearing ability of a person has characteristics such that, usually, the hearing ability deteriorates as the person gets older, and it becomes difficult to hear audio. In particular, in the range in which the frequency is high, the characteristics become noticeable. In the age bracket of 20 to 30 years old, it is possible to satisfactorily hear the sound of the audio-frequency range in an overall manner. However, in the age brackets of 40 to 50 years old and 50 to 60 years old, it becomes difficult to hear sounds having a frequency of about 1 kHz to 2 kHz or higher, and in the age bracket of 60 years old or higher, it become further difficult to hear sounds having a frequency of about 1 kHz to 2 kHz or higher. Such frequency characteristics are due to a decrease in the sensory function due to aging and the deterioration of the ear drum or the like. Therefore, in the first embodiment, audio is more easily heard by performing audio processing.

An example of audio processing for compensating for the deterioration of hearing ability include making higher the frequency characteristics of a predetermined band so as to become characteristics of the age bracket that is one before the age bracket in which the age of the user is contained. For example, if the user is 65 years old, the user is classified into the age bracket of “60 years old or higher”. The hearing ability characteristics of “60 years old or higher” are that it is most difficult to hear sound among all the age brackets, as shown in FIG. 3. Therefore, in the present embodiment, audio processing is performed so that hearing is possible in the state of the frequency characteristics of the age bracket that is one before. When the user is “60 years old or higher”, audio processing is performed so that hearing is possible in the state of the frequency characteristics of “50 to 60 years old”. When the user is “50 to 60 years old”, audio processing is performed so that hearing is possible in the state of the frequency characteristics of “40 to 50 years old”. The amount of correction for compensating for such deterioration of hearing ability is calculated by equation 1 below.

cv(x)=kv(f(x)−g(x)) [Equation 1]

In equation 1, x denotes frequency. f(x) denotes target frequency characteristics after audio processing. g(x) denotes frequency characteristics of the age bracket for the object of processing. cv(x) denotes the amount of correction with respect to frequency. kv is a scaling coefficient for adjusting the correction amount so as to prevent sound volume balance from being disrupted due to audio processing.

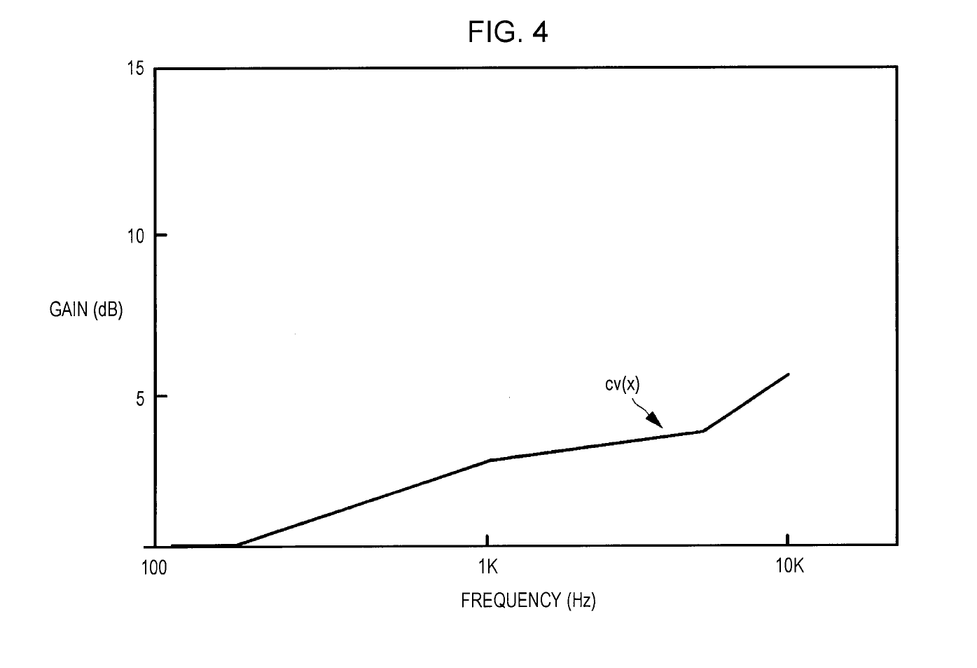

The amount of correction cv(x) calculated by equation 1 above is as shown in FIG. 4. As a result of performing audio processing on the basis of the amount of correction cv calculated by equation 1, the band in which hearing is difficult is compensated for, the frequency characteristics in the auditory sensation are made to approach the target value, and audio is easily heard.

In the foregoing description, target frequency characteristics of the age bracket that is one before the processing target are used. However, target frequency characteristics are not necessarily limited to those of the age bracket that is one before the processing target. Processing may be performed by targeting the frequency characteristics of the age bracket that is two or three age brackets before the processing target. Furthermore, regardless of any age bracket, the frequency characteristics of 20 to 30 years old, which indicate ideal hearing ability characteristics, may be used as a target. However, if the age bracket that is the object of correction and the target age bracket are separated too much, there is a probability that the audio after processing gives the user an uncomfortable feeling. Thus, the target age bracket should preferably be determined by taking this into consideration.

It is possible to identify individual users on the basis of the image obtained by the image-capturing unit 11 by template matching or the like, which is an existing technology. Accordingly, audio processing setting (target frequency characteristic, etc.) for each user is stored in a storage unit (not shown). Then, the user information obtaining unit 13 identifies individual users from the image obtained by the image-capturing unit 11, and the audio processing unit 16 performs audio processing on the basis of the audio processing setting of the identified user. As described above, audio processing different for each user may be performed.

In general, in a case where content, such as a movie or a television program, is to be viewed, the sound the user most wants to hear is considered to be a “voice sound”, such as dialog, narration, or singing. Therefore, by performing the above-mentioned audio processing on a band in which “voice sound” is contained, the “speech” that the user most wants to hear can be accentuated, and a satisfactory audio hearing environment can be realized.

In the present technology, “voice sound” is assumed to refer to sound containing a word uttered by a person or a personified animal or plant other than the person, such as dialog in a movie or a television drama, narration in a television program, conversation, songs, and the like of cast members of a television program.

As methods for detecting “voice sound” from sound, various technologies exist. For example, the technique disclosed in WO2006/016590 can be adopted. Furthermore, in a case where audio is audio for 5.1ch surround, “voice sound”, such as dialog, is output from the center channel, and thus, the above-described audio processing may preferably be performed on the sound of the center channel.

Furthermore, with regard to singing voice, for example, a music section is detected on the basis of the technology disclosed in Japanese Unexamined Patent Application Publication No. 2002-116784, and the sound output from the center channel in that section can be determined to be “voice sound” containing a singing voice.

The conversion processing unit 17 performs processing, such as an inverse Fourier transform (IFFT: Inverse Fast Fourier Transform), on the audio signal supplied from the correction processing unit 16 so as to convert the audio signal from a signal in the frequency domain into a signal in the time domain. Since output is made as audio, it is supplied to an external audio output system.

In the manner described above, the audio processing apparatus 10 is configured. The face detection unit 12, the user information obtaining unit 13, and the audio processing unit 14 can be realized by, for example, executing a program stored in a read only memory (ROM) by a central processing unit (CPU) by using a random access memory (RAM) as a work memory.

However, the face detection unit 12, the user information obtaining unit 13, and the audio processing unit 14 are not limited to those realized by using programs in the manner described above. The audio processing apparatus 10 may be realized as a dedicated device in which hardware having the respective functions of the image-capturing unit 11, the face detection unit 12, the user information obtaining unit 13, and the audio processing unit 14 are combined.

### 1-2. Configuration of Audio Output Apparatus Including Audio Processing Apparatus

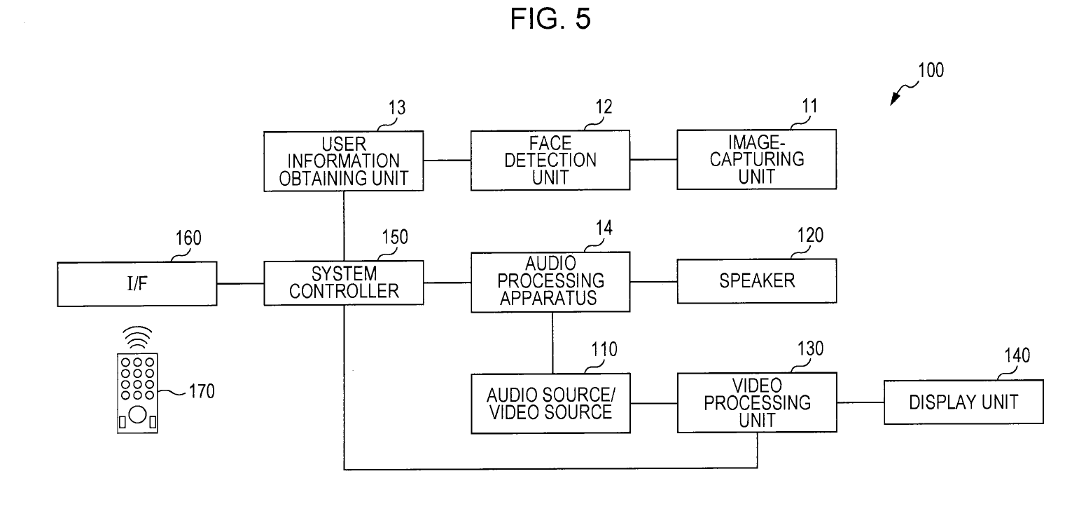

Next, a description will be given of the configuration of an audio output apparatus 100 including the above-mentioned audio processing apparatus 10. FIG. 5 is a block diagram illustrating a configuration of the audio output apparatus 100. The audio output apparatus 100 is configured as an AV (Audio Video) system, which is a so-called “home theater system” that can output audio and can also output video.

The audio output apparatus 100 is constituted by a audio source/video source 110, an audio processing unit 14, a speaker 120, a video processing unit 130, a display unit 140, a system controller 150, an I/F (InterFace) 160, an image-capturing unit 11, a face detection unit 12, and a user information obtaining unit 13. The image-capturing unit 11, the face detection unit 12, the user information obtaining unit 13, and the audio processing unit 14 forming the audio processing apparatus 10 are the same as those described with reference to FIG. 1, and accordingly, the description thereof is omitted.

The audio source/video source 110 supplies video and audio forming the content output from the audio output apparatus 100, or only audio. Examples of content include a television program, a movie, a music, and a radio. Examples of the audio source/video source 110 include a television tuner, a radio tuner, a DVD player, a Blu-ray disc player, and a game machine. The audio data from the audio source/video source 110 is supplied to the audio processing unit 14. Furthermore, the audio data from the audio source/video source 110 is supplied to the video processing unit 130.

The speaker 120 is an audio output means that outputs audio on which processing has been performed by the audio processing unit 14. As a result of the audio being output from the speaker 120, it is possible for the user to listen to the audio from the audio source/video source 110.

In the case where the audio output apparatus 100 is a 5.1ch surround system, the speaker 120 is formed of an Lch front speaker, an Rch front speaker, a center speaker, an Lch rear speaker, an Rch rear speaker, and a subwoofer. Furthermore, in the case where the audio output apparatus 100 is of stereo (2ch) audio, the speaker 120 is formed of an Lch speaker and an Rch speaker. However, the audio output apparatus 100 may be a 6.1ch or 7.1ch surround system other than the above.

In the case where the audio output apparatus 100 is a 5.1ch surround system, audio processing by the audio processing unit 14 may preferably be performed on audio output from the center speaker, the audio containing “voice sound”, such as dialog. The reason for this is that, in the manner described above, “voice sound” is generally assigned to the center channel in the 5.1ch surround system. Furthermore, in the case where the audio output apparatus 100 is a system including a stereo (2ch) speaker, audio processing may preferably be performed on a band in which, voice sound is mainly contained.

The video processing unit 130 performs a predetermined video process, such as resolution conversion, luminance correction, and color correction, on the video signal, and supplies it to the display unit 140. The display unit 140 is a video display means formed of, for example, a liquid crystal display (LCD), a plasma display panel (PDP), or an organic electro luminescence (EL) panel. The video signal supplied from the video processing unit 130 is displayed as a video by the display unit 140. As a result of a video being displayed on the display unit 140, it is possible for the user to view a video from the audio source/video source 110. In a case where the audio output apparatus 100 is intended to reproduce only audio, such as music, the display unit 140 and the video processing unit 130 are unnecessary.

The system controller 150 is formed of, for example, a CPU, a RAM, and a ROM. The ROM has stored therein a program to be read and executed by the CPU. The RAM is used as a work memory for the CPU. The CPU performs control of the entire audio output apparatus 100 by executing the program stored in the ROM.

The I/F 160 receives a control signal transmitted from the remote controller 170 attached to the audio output apparatus 100 by the operation of the user, and outputs it to the system controller 150. The system controller 150 controls the entire audio output apparatus 100 in response to the controller signal from the remote controller 170.

It is noted that all the image-capturing unit 11, the face detection unit 12, the user information obtaining unit 13, and the audio processing unit 14 forming the audio processing apparatus 10 are provided within the same housing. For example, the image-capturing unit 11 may be a so-called WEB camera that is integrally formed with the housing of the display unit 140. In addition, the face detection unit 12 and the user information obtaining unit 13 are provided in the display unit 140, and user information may be supplied to the audio processing unit 14 provided in an external device through a universal serial bus (USB) or a high-definition multimedia interface (HDMI). Furthermore, the image-capturing unit 11 may be formed as independent hardware that is connected through USB, HDMI, or the like.

### 1-3. Audio Processing

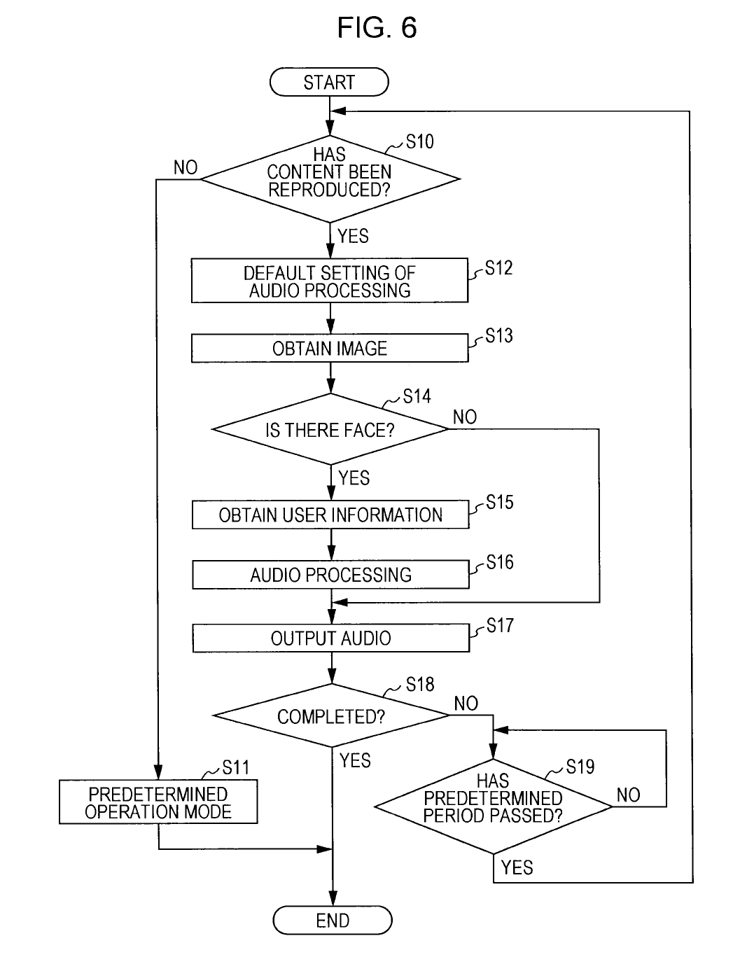

Next, a description will be given of audio processing performed in the audio processing apparatus 10 forming the audio output apparatus 100. FIG. 6 is a flowchart illustrating a flow of audio processing. In the following description, a description will be given of only processing on audio of content that is reproduced by the audio output apparatus 100.

Initially, in step S10, the system controller 150 determines whether or not content has been reproduced in the audio output apparatus 100. When content has not been reproduced, the process proceeds to step S11 (No in step S10). Then, in step S11, the audio output apparatus 100 and the audio processing apparatus 10 enter an operation mode other than the mode in which content is reproduced, for example, a standby mode.

On the other hand, when it is determined in step S10 that the content has been reproduced, the process proceeds to step S12 (Yes in step S10). Next, in step S12, the system controller 150 sets the audio reproduction setting to default setting.

Next, in step S13, the image-capturing unit 11 obtains an image of a user. The obtained image is supplied to the face detection unit 12. Next, in step S14, it is determined whether or not there is a face in the image by performing a face detection process by the face detection unit 12 on the image obtained by the image-capturing unit 11. As a result, the presence or absence of the user is detected. When there is a face in the image, the process proceeds to step S15 (Yes in step S14). In the manner described above, when there is a face in the image, the face image containing the face is supplied to the user information obtaining unit 13.

Next, in step S15, the user information obtaining unit 13 obtains user information on the basis of the face image. In the manner described above, in the present embodiment, user information is the age bracket of the user. The obtained user information is supplied to the audio processing unit 14. Next, in step S16, the audio processing unit 14 performs audio processing on the audio forming the content on the basis of the user information.

Next, in step S17, audio on which predetermined processing has been performed by the audio processing unit 14 is output from the speaker 120. As a result, it is possible for the user to listen to the audio of the content.

Next, the system controller 150 determines in step S18 whether or not the reproduction of the content by the audio output apparatus 100 has been completed. When the reproduction of the content has been completed, the processing of the flowchart of FIG. 6 is completed (Yes in step S18). On the other hand, when the reproduction of the content has not been completed, the process proceeds to step S19 (No in step S18).

Then, in step S19, the system controller 150 determines whether or not a predetermined period has passed after the audio processing has been performed. This predetermined period indicates the time interval in which audio processing is performed. For example, when audio processing is to be performed every 10 minutes, it is determined whether or not 10 minutes have passed after audio processing has been performed previously. However, the predetermined period may be set as desired by the user, or may be preset by the maker that provides the audio output apparatus 100. Audio processing may be performed at a preset predetermined timing, such as before the reproduction of content.

When it is determined in step S19 that the predetermined period has not passed, the determination of step S19 is repeated until the predetermined period has passed (No in step S19). On the other hand, when it is determined in step S19 that the predetermined period has passed, the process returns to step S10 (Yes in step S19). Then, audio processing is performed starting from step S10 again.

In the manner described above, audio processing in the first embodiment of the present technology is performed. In the first embodiment, by increasing the frequency characteristics of audio, the band in which “voice sound” that the user would like most to listen to is contained is accentuated. As a result, it becomes easier to listen to “voice sound”, and it is possible to realize a hearing environment satisfactory mainly for old age users.

### 2. Second Embodiment

### 2-1. Audio Processing

Next, a second embodiment of the present technology will be described. The configurations of the audio processing apparatus 10 and the audio output apparatus 100 in the second embodiment are the same as those of the first embodiment, and accordingly, the descriptions thereof are omitted.

In the first embodiment, in order that the user becomes easy to listen to audio, a process for increasing frequency characteristics of a band containing “voice sound” is performed. However, a method for making the user easy to listen to audio is not limited to that process.

In the second embodiment, the audio processing apparatus 10 reduces the level of audio other than “voice sound” (hereinafter referred to as background sound), with the result that, relatively, “voice sound” is made to be noticeable and easier to listen to, so that a viewing environment satisfactory for the user is provided.

When the audio processing apparatus 10 that is a 5.1ch surround system is to be applied, it is recommended that audio processing be performed on the audio of the channel other than the center channel to which “voice sound”, such as dialog, is assigned mainly. Furthermore, in the case of stereo (2ch), it is recommended that audio processing is performed on audio other than the “voice sound” detected by a technique of detecting “voice sound” from the above-mentioned audio in the first embodiment.

The amount of correction for reducing background sound is calculated by equation 2 below.

cb(x)=kb(f(x)−a−g(x)) [Equation 2]

In equation 2, x denotes frequency. f(x) denotes frequency characteristics serving as a processing target. a denotes the amount of gain reduction. Therefore, “f(x)−a” denotes the frequency characteristics for the processing target. g(x) denotes the frequency characteristics of an age bracket for the processing target. cb(x) denotes an amount of correction with respect to the frequency. kb is a scaling coefficient for adjusting the amount of correction in order to prevent the sound volume balance from being disrupted.

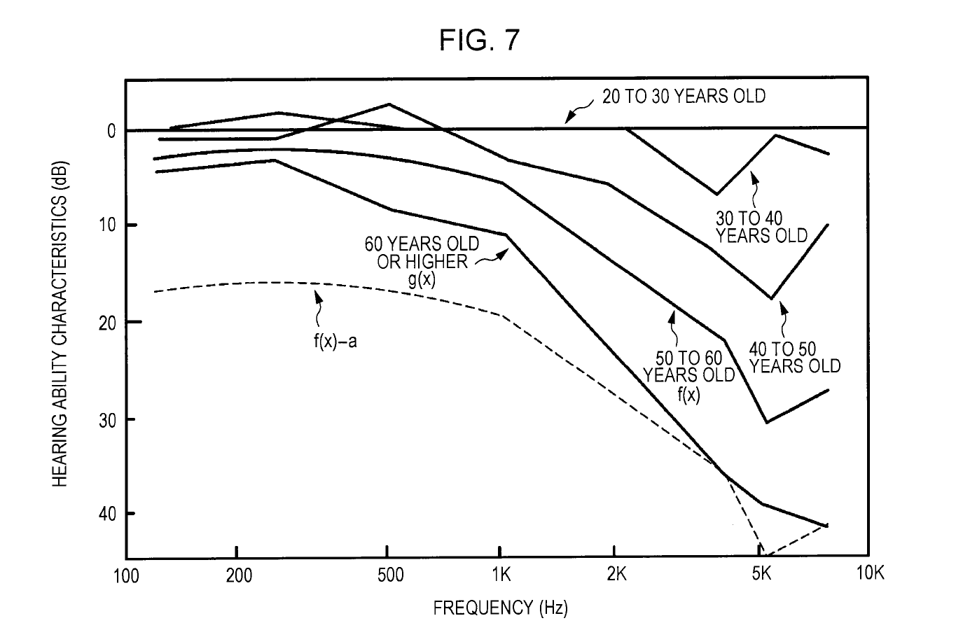

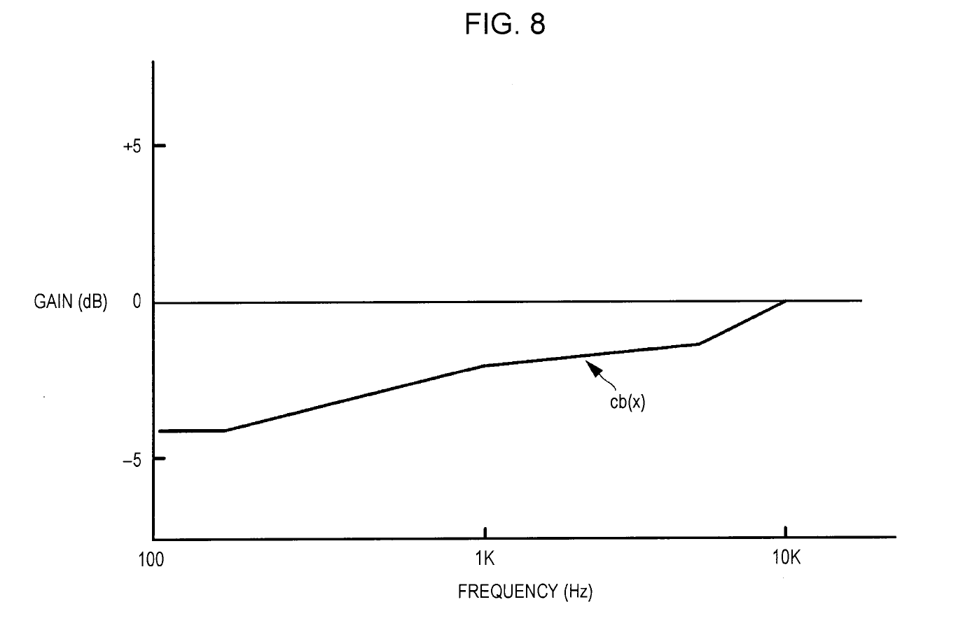

Audio processing using equation 2 will be described by using a specific example with reference to FIG. 7. In FIG. 7, the 60 years old or higher bracket is denoted as a processing target g(x), and the 50 to 60 years old bracket, which is one age bracket lower, is denoted as a process reference f(x). The characteristics indicated using a dashed line become target characteristics “f(x)−a”. As can be seen from FIG. 7, the target “f(x)−a” is that the frequency characteristics of f(x) are reduced by the gain reduction amount a. The amount of correction cb(x) is that shown in FIG. 8.

By performing a process for reducing the frequency characteristics by the amount cb(x) with respect to the background sound, when “kb=1” is set, the processing target g(x) becomes target “f(x)−a”. As described above, as a result of the frequency characteristics of the background sound being reduced, “voice sound” becomes relatively noticeable, and it becomes easy to hear “voice sound”.

As can be seen from FIG. 7, regarding the characteristics of the hearing ability of a person, as a person gets older, in particular, the high frequency band decreases greatly, and the balance becomes poor. Therefore, rather than setting the frequency characteristics of the processing target g(x), which are reduced simply by the reduction amount a, as the target characteristics, the process reference f(x) for the age bracket that is one before the processing target g(x), which is reduced by the reduction amount a, are set as the target characteristics, making it possible to correct the balance of the frequency characteristics. As a result, it is possible to realize a more satisfactory hearing environment.

In the foregoing description, the frequency characteristics of the age bracket that is one before the processing target are set as the frequency characteristics for the reference of the process. However, the reference of the process is not necessarily limited to the age bracket that is one before the correction object. The age bracket that is two or three before may be used as the reference of the process.

The second embodiment may be performed only singly, and may be combined with the first embodiment and used. Specifically, while the audio processing apparatus 10 compensates for “voice sound” by using the method of the first embodiment, the audio processing apparatus 10 reduces “background sound” by using the method of the second embodiment. As a result, it is possible to make more noticeable “voice sound” that a user generally wants to hear, and it is possible to realize a satisfactory hearing environment.

### 3. Third Embodiment

### 3-1. Configuration of Audio Output Apparatus Including Audio Processing Apparatus

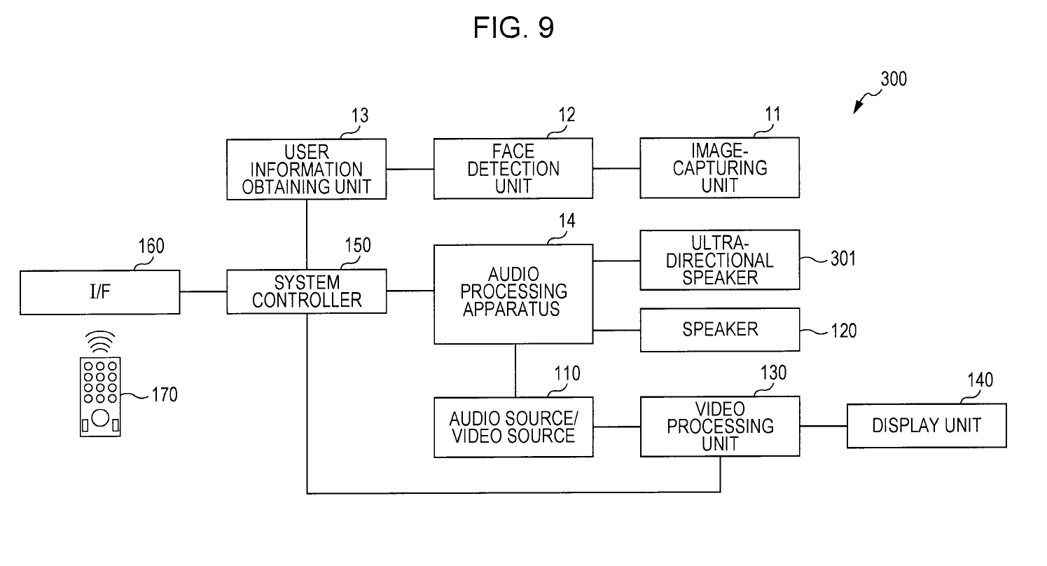

Next, a third embodiment of the present technology will be described. FIG. 9 is a block diagram illustrating the configuration of an audio output apparatus 300 in the third embodiment.

The third embodiment differs from the first embodiment in that a directional speaker 301 is provided. A directional speaker is a speaker having high directivity in one direction. Examples thereof include a parametric speaker and a plane speaker, which output ultrasonic waves having nonlinear characteristics and high directivity. By using a directional speaker, audio can be conveyed to only the user who exists in a specific space range. In addition to a directional speaker, a speaker called an ultra-directional speaker may be used. Except for the directional speaker, the configuration is the same as that of the first embodiment, and accordingly, the description thereof is omitted. The configuration of the audio processing apparatus 10 and the directional speaker 301 corresponds to that of the audio output apparatus in the claims.

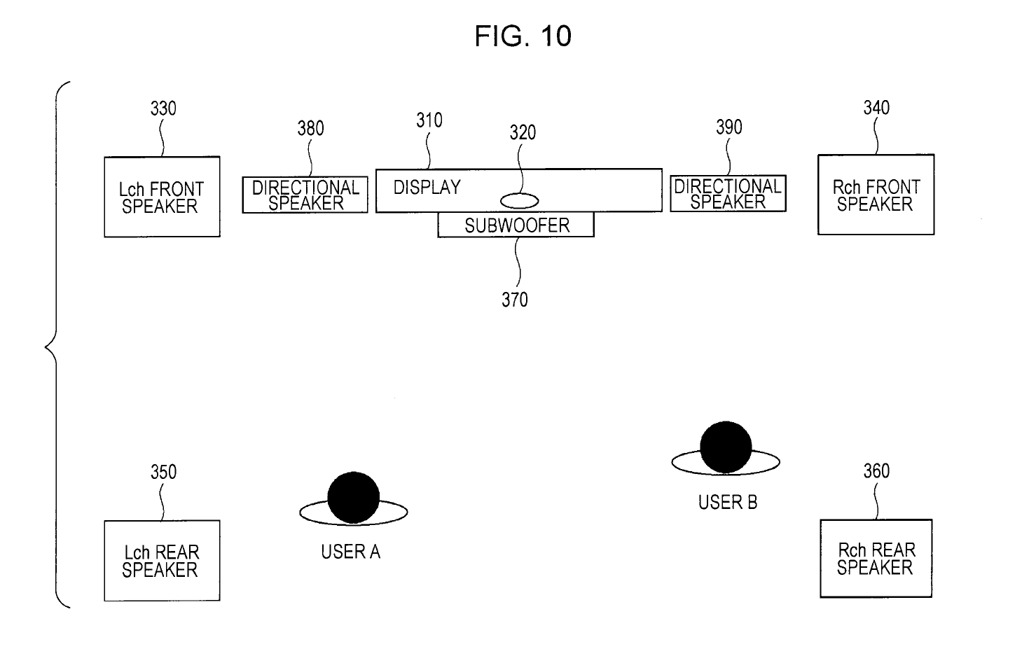

FIG. 10 is a schematic view of an audio output apparatus 300 in the third embodiment. A display 310 outputs a video forming the content, such as a movie and a television program. The display 310 corresponds to the display unit 140 in the block diagram of FIG. 9. A camera 320 is integrally provided with the display in the upper area of the display. The camera 320 forms the image-capturing unit 11 in the block diagram of FIG. 9. However, the camera 320 may be configured as independent hardware, which can be connected through USB, HDMI, or the like.

An Lch front speaker 330, an Rch front speaker 340, an Lch rear speaker 350, and an Rch rear speaker 360 are audio output means, and output corresponding audio. A subwoofer 370 is a low tone dedicated speaker. These speakers correspond to the speaker 120 in the block diagram of FIG. 9. As described above, in FIG. 9, the audio output apparatus 300 is configured as a 5.1ch surround system. However, a home theater system, which is the audio output apparatus 300, is not limited to the above-mentioned configuration. The audio output means may be formed of only the directional speakers. Furthermore, the speaker and the subwoofer may be integrally configured with an AV rack.

Directional speakers 380 and 390 are provided on either side of the display 310. Audio output from the center speaker in the 5.1ch surround system is output from the directional speakers 380 and 390. That is, speaker speech, such as dialog and narration, is output. Therefore, there is no discrimination between Lch and Rch in the directional speakers 380 and 390. The total number and the arrangement of directional speakers are not limited to the example shown in FIG. 9.

In the third embodiment, the audio of the center channel, on which the audio control process in the first embodiment and/or second embodiment has been performed, is output from the directional speakers 380 and 390, so that “voice sound”, which is the sound the user wants to hear most, is made easier to hear, and a satisfactory hearing environment can be realized.

### 4. Fourth Embodiment

### 4-1. Configuration of Audio Output Apparatus

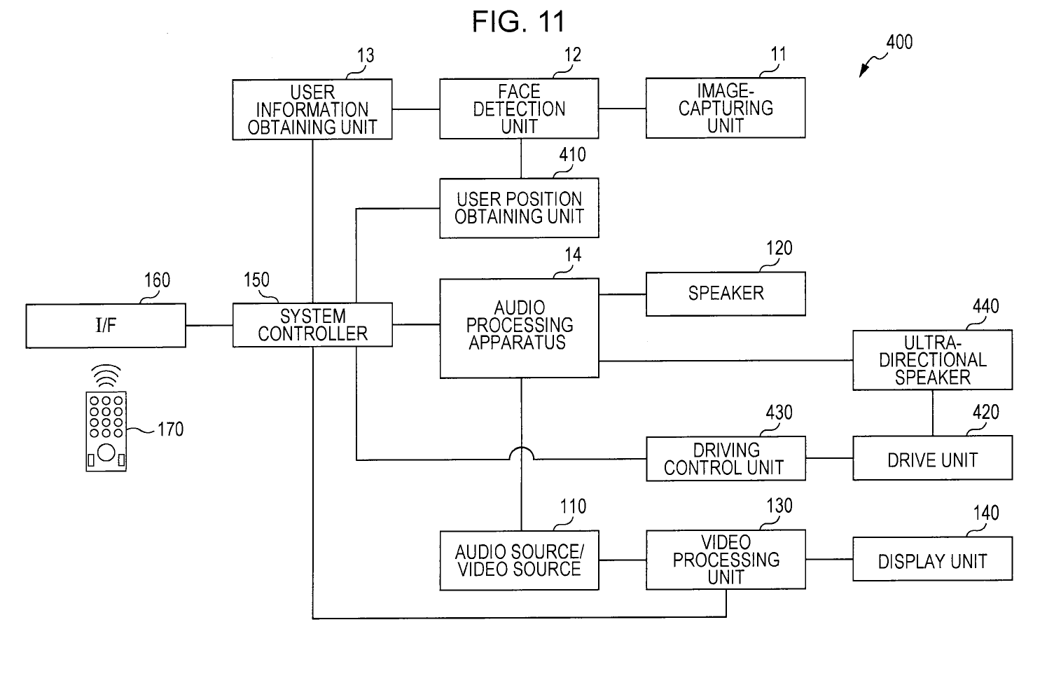

Next, a fourth embodiment of the present technology will be described. FIG. 11 is a block diagram illustrating the configuration of an audio output apparatus 400 in the fourth embodiment. The fourth embodiment differs from the third embodiment in that a user position obtaining unit 410, a driving unit 420, and a driving control unit 430 are provided. The configuration other than the driving unit 420 and the driving control unit 430 is the same as in the first to third embodiments. Thus, the description thereof is omitted.

The user position obtaining unit 410 obtains the position of the user who views content by using an audio output apparatus. For example, the user position obtaining unit 410 obtains the position of the user on the basis of the image obtained by the camera of the image-capturing unit 11. The position of the user can be obtained, for example, as an angle and a distance with respect to a position serving as a reference (camera of the image-capturing unit 11, etc.) on the basis of the calculation result of the relative position of the user with respect to the optical axis of the camera of the image-capturing unit 11, information on the position and the angle of the camera of the image-capturing unit 11, and the like.

The user position obtaining unit 410 is realized by executing a program by a CPU or dedicated hardware having the functions. However, the method is not limited to such a method, and any method may be used as long as the method can obtain the position of the user. For example, the position of the user may be detected by using a sensor, for example, an infrared sensor, a so-called human detection sensor. Furthermore, an active method range-finding sensor that measures the distance up to the user by using reflection when an infrared ray is output, or a passive method range-finding sensor that measures the distance on the basis of the luminance obtained by detecting the luminance information of the subject by the sensor may be used. The user position information obtained by the user information obtaining unit 13 is supplied to the driving control unit 430 through the system controller 150.

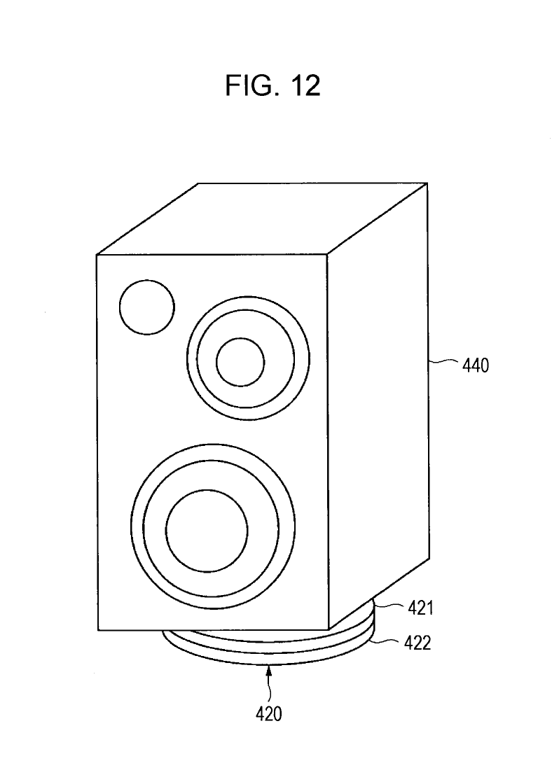

The driving unit 420 is formed of, for example, a support body 422, a rotational body 421, and a pan shaft (not shown) so as to be rotatable, as shown in FIG. 12. The rotational body 421 of the driving unit 420 is configured so as to be rotatable by 360 degrees on the support body 422 about the pan shaft by the driving force of a driving motor (not shown) in a state in which the directional speaker 440 is mounted. As a result, it becomes possible for the directional speaker to be oriented in any direction by 360 degrees. The configuration of the driving unit 420 is not limited to that shown in FIG. 12. Any configuration may be used as long as the orientation of the directional speaker 440 can be changed. For example, the directional speaker may be hung from the ceiling so as to be rotatable. Furthermore, not limited to a pan operation, there may also be a configuration in which a tilt operation is possible.

The driving control unit 430 controls the operation of the driving unit 420. Specifically, the rotational direction, the rotation speed, the rotation angle, etc., of the driving motor of the driving unit 420 are controlled on the basis of the position of the user, which is indicated by the user position information, so that the user is contained in the range in which the directional speaker 440 has directivity. The driving control unit 430 transmits a control signal to the driving unit 420 so that the driving unit 420 operates. The driving control unit 430 is realized by executing a program by a CPU or by dedicated hardware having the functions.

In a case where plural (for example, two) users exist, the user position obtaining unit 410 may calculate the center of the positions of the plurality of users, and may supply the center position as user position information to the driving control unit 430. In this case, the driving control unit 430 controls the driving unit 420 so that the center position of the plurality of users is contained in a range in which the directional speaker 440 has directivity.

### 4-2. Processing in the Fourth Embodiment

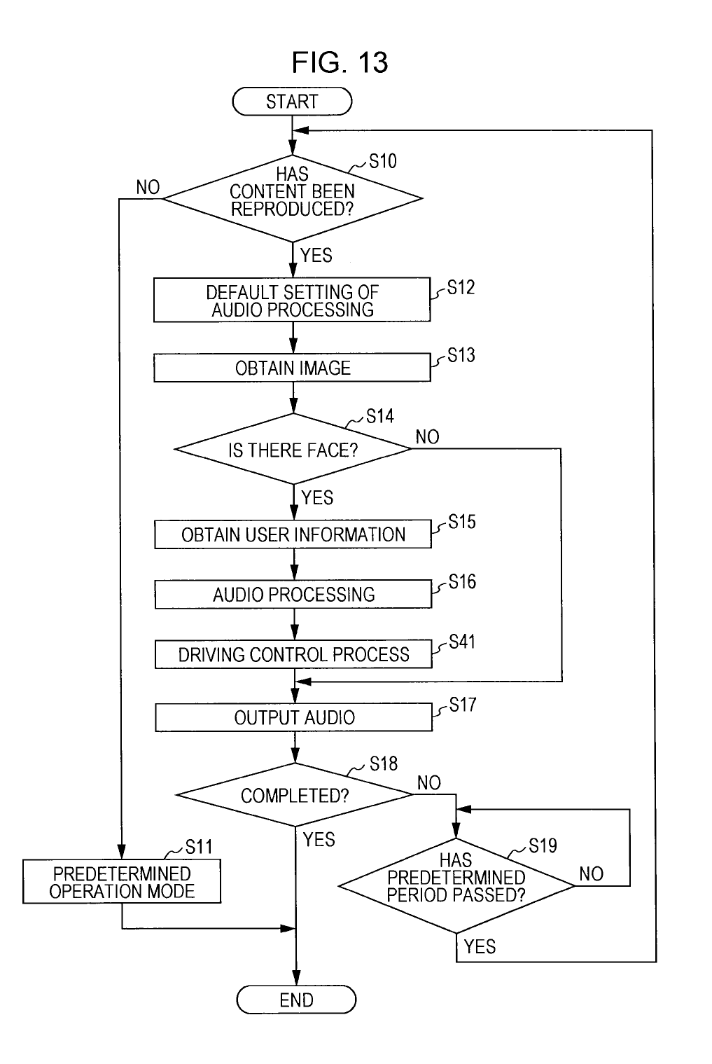

In the fourth embodiment, in addition to an audio processing in the first and/or second embodiments, a process for causing the driving unit 420 to operate on the basis of the position of the user is performed. FIG. 13 is a flowchart illustrating the flow of processing in the fourth embodiment.

In the flowchart of FIG. 13, processes (steps S10 to S19) other than step S41 are the same as those in the first embodiment. In the fourth embodiment, in step S41, the driving control unit 430 performs a process for controlling the driving unit 420. Next, in step S17, audio on which audio processing has been performed is output from the directional speaker 440 whose orientation has been adjusted in accordance with the position of the user.

According to the fourth embodiment, in addition to the audio processing by the first and/or second embodiments, audio is output in a state in which the user is positioned in the range in which the directional speaker has directivity. Consequently, it becomes easier for the user to hear audio. As a result, it is possible to realize a satisfactory hearing environment.

### 5. Fifth Embodiment

### 5-1. Configuration of Audio Output Apparatus Including Audio Processing Apparatus

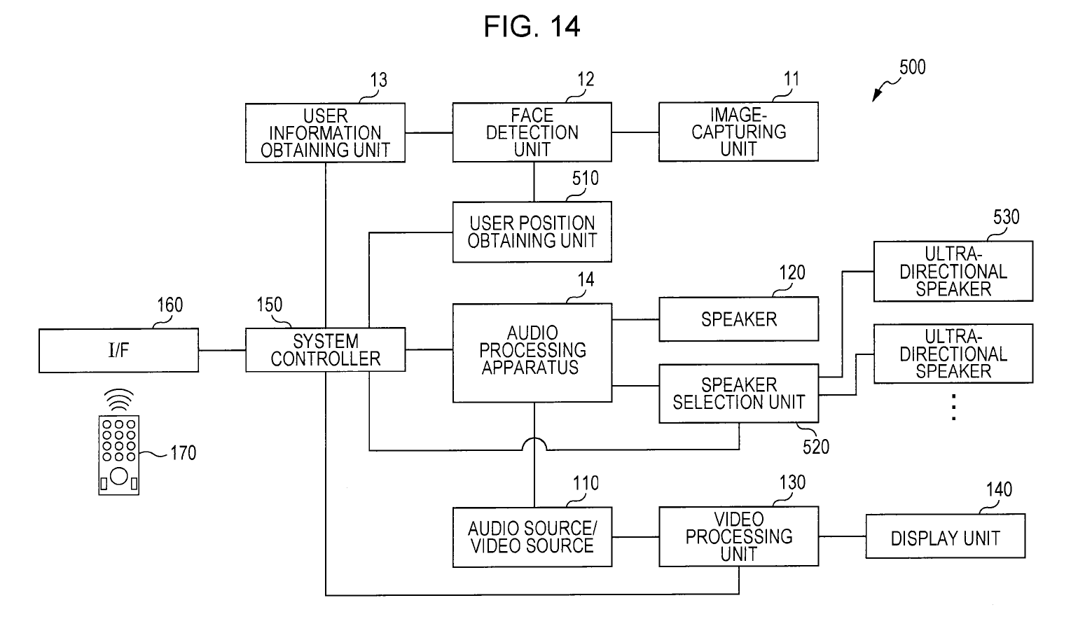

Next, a fifth embodiment of the present technology will be described. FIG. 14 is a block diagram illustrating the configuration of an audio output apparatus 500 in the fifth embodiment. The fifth embodiment differs from the third embodiment in that a user position obtaining unit 510 and a speaker selection unit 520 are provided. Since the user position obtaining unit 510 is the same as the user position obtaining unit 410 in the fourth embodiment, the description thereof is omitted. Furthermore, the configuration other than the user position obtaining unit 510 and the speaker selection unit 520 is the same as those in the first to third embodiments, and thus, the description thereof is omitted.

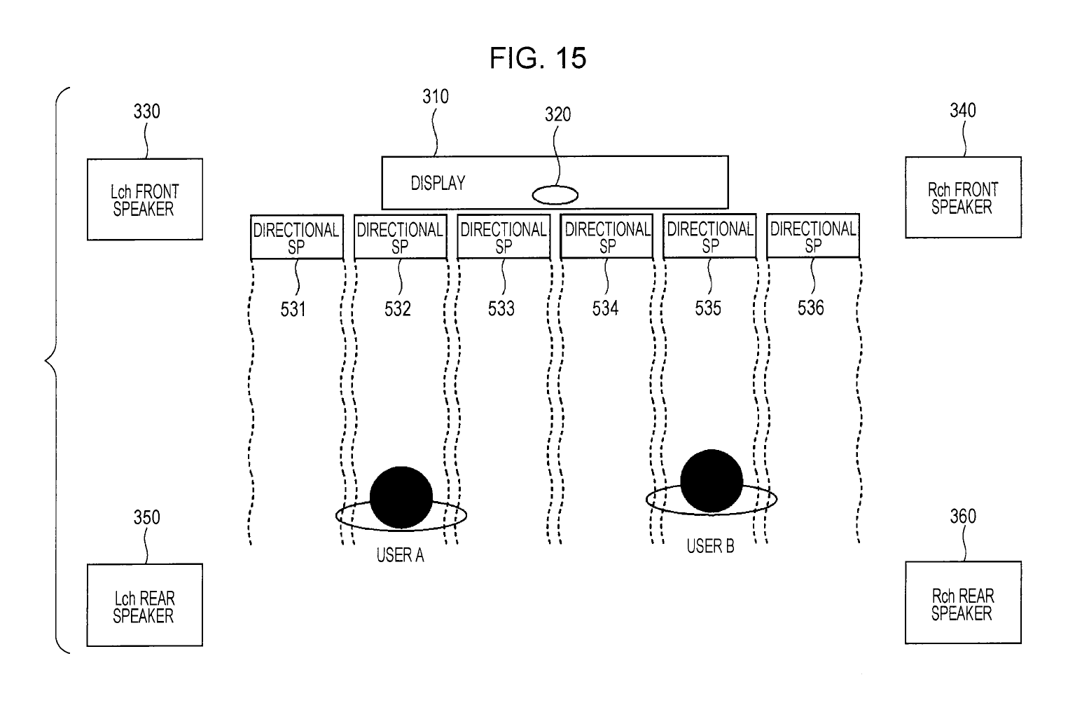

In the fifth embodiment, as shown in FIG. 15, a plurality of directional speakers are arranged side by side to each other. In FIG. 14, a total of six directional speakers, that is, a first directional speaker 531, a second directional speaker 532, a third directional speaker 533, a the fourth directional speaker 534, a fifth directional speaker 535, and a sixth directional speaker 536, are arranged side by side to each other. However, the number of directional speakers is not limited to six as shown in FIG. 15, and may be any number. The parallel arrangement position of directional speakers is not limited to the front of the display.

The speaker selection unit 520 selects which directional speaker from among a plurality of directional speakers audio should be output on the basis of the position of the user, which is obtained by the user position obtaining unit 510. The speaker selection unit 520 includes, for example, switching circuits corresponding to the number of directional speakers, and selects a speaker by switching the supply source of the audio signal from the audio processing unit 14. Furthermore, the selection may be performed by switching on/off of the directional speaker by transmitting a predetermined control signal to each directional speaker.

For example, a case is assumed in which the positions of the user A and the user B, and the range in which each directional speaker has directivity are as shown in FIG. 14. The dashed line extending from each directional speaker indicates a range in which each directional speaker has directivity.

In the case of the state shown in FIG. 15, the speaker selection unit 520 causes audio to be output from the second directional speaker 532 toward the user A. Furthermore, the speaker selection unit 520 causes audio to be output from the fifth directional speaker 535 toward the user B. As described above, the selection of the speaker is performed.

### 5-2. Processing in Fifth Embodiment

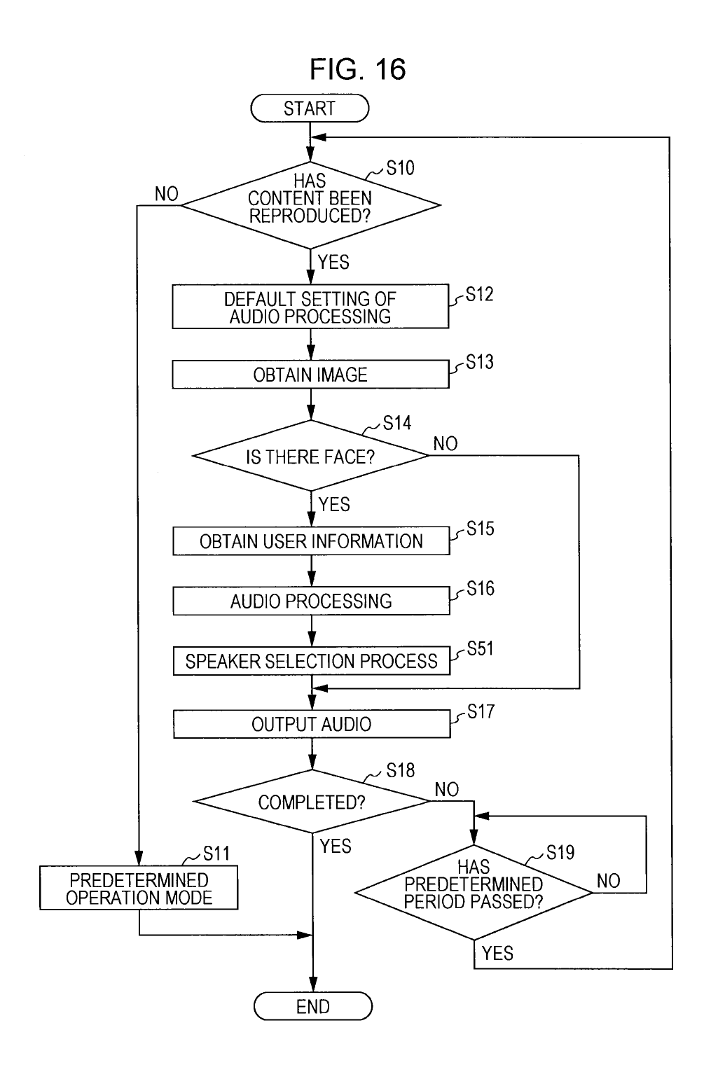

In the fifth embodiment, in addition to audio processing in the first and/or second embodiments, a process for causing the driving unit 420 to operate on the basis of the position of the user is performed. FIG. 16 is a flowchart illustrating the flow of processing in the fifth embodiment.

In the flowchart of FIG. 16, processes (steps S10 to S19) other than step S51 are the same as those in the first embodiment. In the fifth embodiment, in step S51, a process in which the speaker selection unit 520 selects a directional speaker from which audio is output is performed. Next, in step S17, audio on which audio processing has been performed is output from the directional speaker whose orientation has been adjusted in accordance with the position of the user.

According to the fifth embodiment, in addition to the audio processing by the first and/or second embodiments, audio is output in a state in which the user is positioned in the range in which the directional speaker has directivity. Consequently, it becomes easier for the user to hear audio. As a result, it is possible to realize a satisfactory hearing environment.

### 6. Modification

In the foregoing, embodiments of the present technology have been described specifically. The present technology is not limited to the above-described embodiments, and various modifications based on the technical concept of the present technology are possible.

In the above-described embodiments, the age bracket of users is used as user information. In addition to age, the gender of a user may be obtained as user information, and an audio correction process may be performed on the basis of the gender of the user. The frequency of sound that human beings can perceive differs depending on age and also gender. Consequently, by performing an audio correction process on the basis of gender, it is considered that a more satisfactory viewing environment can be provided.

The audio processing apparatus can be applied to any device as long as it is a device that outputs audio, such as a phone set, a mobile phone, a smartphone, or a headphone, in addition to an audio output apparatus that reproduces content, which is described in the embodiments.

Furthermore, the present technology can take the following configurations.
(1) An audio processing apparatus including:
   a user detection unit that detects the presence or absence of a user;
   a user information obtaining unit that obtains user information about a user that is detected by the user detection unit; and
   an audio processing unit that performs a process for accentuating predetermined audio contained in input audio on the basis of the user information.
(2) The audio processing apparatus as set forth in the above (1), wherein the user information obtaining unit estimates the age of the user and sets the age as the user information.
(3) The audio processing apparatus as set forth in the above (1) or (2), wherein the audio processing unit accentuates the predetermined audio by increasing frequency characteristics of a band in which the predetermined audio is contained.
(4) The audio processing apparatus as set forth in one of the above (1) to (3), wherein the audio processing unit accentuates the predetermined audio by decreasing frequency characteristics of a band other than the band in which the predetermined audio is contained.
(5) The audio processing apparatus as set forth in one of the above (1) to (4), wherein the audio processing unit accentuates the predetermined audio by increasing frequency characteristics of audio of a channel in which the predetermined audio is mainly contained.
(6) The audio processing apparatus as set forth in one of the above (1) to (5), wherein the audio processing unit accentuates the predetermined audio by decreasing frequency characteristics of audio of a channel other than the channel in which the predetermined audio is mainly contained.
(7) The audio processing apparatus as set forth in one of the above (1) to (6), wherein the predetermined audio is voice.
(8) An audio processing method including:
   detecting the presence or absence of a user;
   obtaining user information about the detected user; and
   accentuating predetermined audio contained in input audio on the basis of the user information.
(9) An audio output apparatus including:
   an audio processing apparatus including
      a user detection unit that detects the presence or absence of a user,
      a user information obtaining unit that obtains user information about a user that is detected by the user detection unit, and
      an audio processing unit that performs a process for accentuating predetermined audio contained in input sound on the basis of the user information; and
   a directional speaker that outputs audio on which processing has been performed by the audio processing apparatus.
(10) The audio output apparatus as set forth in the above (9), further including:
   a driving unit that causes the directional speaker to perform a pan operation;
   a driving control unit that controls the driving unit; and
   a user position obtaining unit that obtains a position of the user,
   wherein the driving control unit controls the operation of the driving unit so that the user is positioned within a range in which the directional speaker has directivity on the basis of the position of the user, which is obtained by the user position obtaining unit.
(11) The audio output apparatus as set forth in the above (9) or (10), further including:
   a speaker selection unit that selects the directional speaker for outputting the audio from among a plurality of directional speakers; and
   a user position obtaining unit that obtains a position of the user
   wherein the plurality of directional speakers are arranged side by side, and
   wherein the speaker selection unit selects the directional speaker that outputs the audio so that the user is positioned within the range of directivity of one of the plurality of directional speakers on the basis of the position of the user, which is obtained by the user position obtaining unit.

The present application contains subject matter related to that disclosed in Japanese Priority Patent Application JP 2011-194557 filed in the Japan Patent Office on Sep. 7, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An audio processing apparatus comprising:
a user detection unit that detects the presence or absence of a user;
a user information obtaining unit that obtains user information about a user that is detected by the user detection unit; and
an audio processing unit that performs a process for accentuating predetermined audio contained in input audio on the basis of the user information.

2. The audio processing apparatus according to claim 1, wherein the user information obtaining unit estimates the age of the user and sets the age as the user information.

3. The audio processing apparatus according to claim 1, wherein the audio processing unit accentuates the predetermined audio by increasing frequency characteristics of a band in which the predetermined audio is contained.

4. The audio processing apparatus according to claim 1, wherein the audio processing unit accentuates the predetermined audio by decreasing frequency characteristics of a band other than the band in which the predetermined audio is contained.

5. The audio processing apparatus according to claim 1, wherein the audio processing unit accentuates the predetermined audio by increasing frequency characteristics of audio of a channel in which the predetermined audio is mainly contained.

6. The audio processing apparatus according to claim 1, wherein the audio processing unit accentuates the predetermined audio by decreasing frequency characteristics of audio of a channel other than the channel in which the predetermined audio is mainly contained.

7. The audio processing apparatus according to claim 1, wherein the predetermined audio is voice.

8. An audio processing method comprising:
detecting the presence or absence of a user;
obtaining user information about the detected user; and
accentuating predetermined audio contained in input audio on the basis of the user information.

9. An audio output apparatus comprising:
an audio processing apparatus including
a user detection unit that detects the presence or absence of a user,
a user information obtaining unit that obtains user information about a user that is detected by the user detection unit, and
an audio processing unit that performs a process for accentuating predetermined audio contained in input sound on the basis of the user information; and
a directional speaker that outputs audio on which processing has been performed by the audio processing apparatus.

10. The audio output apparatus according to claim 9, further comprising:
a driving unit that causes the directional speaker to perform a pan operation;
a driving control unit that controls the driving unit; and
a user position obtaining unit that obtains a position of the user,
wherein the driving control unit controls the operation of the driving unit so that the user is positioned within a range in which the directional speaker has directivity on the basis of the position of the user, which is obtained by the user position obtaining unit.

11. The audio output apparatus according to claim 9, further comprising:
a speaker selection unit that selects the directional speaker for outputting the audio from among a plurality of directional speakers; and
a user position obtaining unit that obtains a position of the user
wherein the plurality of directional speakers are arranged side by side, and
wherein the speaker selection unit selects the directional speaker that outputs the audio so that the user is positioned within the range of directivity of one of the plurality of directional speakers on the basis of the position of the user, which is obtained by the user position obtaining unit.
